(19) United States
(12) Patent Application Publication
(10) Pub. No.: US 2024/0229237 A9
(43) Pub. Date: Jul. 11, 2024

(54) ALD DEPOSITION METHOD AND SYSTEM

(71) Applicant: ASM IP Holding B.V., Almere (NL)

(72) Inventors: Dieter Pierreux, Pepingen (BE); Theodorus G.M. Oosterlaken, Oudewater (NL)

(21) Appl. No.: 18/491,546

(22) Filed: Oct. 20, 2023

Related U.S. Application Data
(60) Provisional application No. 63/380,685, filed on Oct. 24, 2022.

(51) Int. Cl. C23C 16/455

(52) U.S. Cl. CPC C23C 16/45527; C23C 16/45544

(57) ABSTRACT

A method and system for depositing a material on one or more substrates by atomic layer deposition. The method comprising a step of performing a pulse (1) of a precursor of said material, wherein at least one of the average flow rate (f) and the average partial pressure (r) of said precursor over a first half (2) of the pulse (1) is higher than over a second half (3) of the pulse (1).

### CROSS-REFERENCE TO RELATED APPLICATION(S)

This application claims the benefit of U.S. Provisional Application 63/380,685 filed on Oct. 24, 2022, the entire contents of which are incorporated herein by reference.

### FIELD OF DISCLOSURE

The present disclosure relates to the field of atomic layer deposition (ALD), and more particularly to the field of batch ALD.

### BACKGROUND OF THE DISCLOSURE

The cost of ALD precursors may have a significant impact on the costs of products formed by ALD. This may especially be true for the deposition of ALD layers on complex substrates or on a plurality of parallel substrates. In such cases, in order to ensure a complete and uniform coverage of the substrate(s), a relatively large amount of precursor per pulse may be used compared to the situation where a single flat substrate of equivalent surface area must be coated. In the case of complex substrate, a reason for this may be that it takes time for the ALD precursor to cover the entire surface, including the most hidden surface, of a complex substrate such as a substrate comprising deep trenches. In the case of the simultaneous deposition on a plurality of parallel substrates, the small distance between the substrates may hinder the diffusion of the precursor to surfaces within the substrates stack.

There may therefore, be a need in the art for new methods and systems providing a low precursor consumption and a good substrate coverage uniformity.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

It may be an object of the present disclosure to provide good methods, systems, computer programs, and computer-readable media for depositing a material on one or more substrates by atomic layer deposition.

The above objective may be accomplished by a method, a system, a computer program, and a computer-readable medium according to the present disclosure.

In a first aspect, the present disclosure relates to a method for depositing a material on one or more substrates by atomic layer deposition. The method may comprise a step of performing a pulse of a precursor of said material, wherein at least one of the average flow rate and the average partial pressure of said precursor over a first half of the pulse comprising the start of the pulse may be higher than over a second half of the pulse comprising the end of the pulse.

In a second aspect, the present disclosure relates to a system for depositing a material on a substrate comprising:
a process chamber,
a heater for heating the process chamber,
a precursor flow control valve controlling a flow of a precursor to the process chamber,
a pressure control valve downstream of the process chamber for controlling a flow of gas from the process chamber to a gas exhaust module for removing gas from the process chamber, and a control unit operably connected to the precursor flow control valve and/or the pressure control valve and provided with a memory. The control unit may be configured for executing an atomic layer deposition method stored in the memory by controlling the precursor flow valve to provide a pulse of the precursor whereby the precursor flow control valve and or the pressure control valve may be controlled to have at least one of the average flow rate and the average partial pressure of said precursor over a first half of the pulse higher than over a second half of the pulse.

In a third aspect, the present disclosure relates to a computer program comprising instructions to cause the system of the second aspect to execute the method of the first aspect.

In a fourth aspect, the present disclosure relates to a computer-readable medium having stored thereon the computer program of the third aspect.

It may be an advantage of embodiments of the present disclosure that a low precursor consumption can be achieved, especially during ALD on complex substrates or on a plurality of parallel substrates.

It may an advantage of embodiments of the present disclosure that a good substrate coverage uniformity can be achieved, especially during ALD on complex substrates or on a plurality of parallel substrates.

It may be an advantage of embodiments of the present disclosure that they allow for a low precursor consumption for a particular coverage and/or for a high coverage at a particular precursor consumption.

### BRIEF DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

Like reference numbers will be used for like elements in the drawings unless stated otherwise. Reference signs in the claims shall not be understood as limiting the scope.

FIG. 1 is a plot of a precursor parameter as a function of time for the prior art.

FIG. 2a are plots of a precursor consumption, growth per cycle, and efficiency as a function of time for the prior art where the precursor flow is constant over the time of a pulse.

FIG. 2b are plots of a precursor consumption, growth per cycle, and efficiency as a function of time for an embodiment of the present disclosure where the precursor flow is decreased over the time of a pulse.

FIG. 3 is a plot of ALD process parameters as a function of time for the prior art.

FIGS. 4 to 8 show plots of a precursor parameter as a function of time in embodiments of the present disclosure.

FIG. 9 is a plot of ALD process parameters as a function of time for an embodiment of the present disclosure.

FIG. 10 shows an illustrative system for depositing a material by one or more substrates by atomic layer deposition according to illustrative aspects of the disclosure.

In the different figures, the same reference signs refer to the same or analogous elements.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

Furthermore, the terms first, second, third, and the like in the description and in the claims, are used for distinguishing between similar elements and not necessarily for describing a sequence, either temporally, spatially, in ranking, or in any other manner. It is to be understood that the terms so used are interchangeable under appropriate circumstances and that the embodiments of the disclosure described herein are capable of operation in other sequences than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps, or components as referred to, but does not preclude the presence or addition of one or more other features, integers, steps or components, or groups thereof. The term “comprising” therefore covers the situation where only the stated features are present (and can therefore always be replaced by “consisting of” in order to restrict the scope to said stated features) and the situation where these features and one or more other features are present. The word “comprising” according to the disclosure therefore also includes as one embodiment that no further components are present. Thus, the scope of the expression “a device comprising means A and B” should not be interpreted as being limited to devices consisting only of components A and B. It means that with respect to the present disclosure, the only relevant components of the device are A and B.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures, or characteristics may be combined in any suitable manner, as would be apparent to one of ordinary skill in the art from this disclosure, in one or more embodiments.

Similarly, it should be appreciated that in the description of exemplary embodiments of the disclosure, various features of the disclosure are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed disclosure requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the disclosure.

In the description provided herein, numerous specific details are set forth. However, it is understood that embodiments of the disclosure may be practiced without these specific details. In other instances, well-known methods, structures, and techniques have not been shown in detail in order not to obscure an understanding of this description.

The first aspect of the present disclosure relates to a method for depositing a material on one or more substrates by atomic layer deposition. The method is typically performed in a reactor.

The method is general and applicable to any ALD process. It may be applicable to any material that can possibly be deposited by ALD. It may also applicable to any substrate on which an ALD process can be applied. In embodiments, the one or more substrates may be semiconductor substrates. This may be advantageous because they are widely used in the fabrication of electronic circuits, a field where cost reduction and reliability are constant challenged by the fast pace at which the technology evolves. The disclosure may be applicable for depositing a material on one substrate, or on a plurality of substrates. The present disclosure is particularly useful when the substrate has a topography. Indeed, the presence of a topography may make some parts of the substrate surface more difficult to reach by the precursors than other parts. As a consequence, the amount of precursor needed to achieve a uniform coverage of the substrate may increase much when a topography is present.

In embodiments, at least one of the one or more substrates may comprise a feature having an aspect ratio of at least 1, preferably of at least 2, at a surface thereof. Such a feature may present surfaces that are particularly difficult to reach for the precursor. Achieving the uniform coverage of the substrate surface comprising said feature tend, therefore, to consume a lot of the precursor or to yield incomplete coverage. It may be an advantage of embodiments of the present disclosure that they are particularly apt at allowing for a low precursor consumption for a particular coverage and/or for a high coverage at a particular precursor consumption in the case of such substrates resenting high aspect ratio features. In embodiments, said feature may be a trench.

The present disclosure may particularly be useful when a plurality of substrates needs to be coated at once. Indeed, in such cases, the presence of neighbouring substrates amper the access to each substrate, thereby increasing precursor consumption and/or decreasing coverage. This may especially be true when the substrates are parallel to each other and separated by a small distance. In embodiments, the one or more substrates may be a plurality of substrates mutually separated by a distance of from 3 mm to 10 cm, preferably from 3 mm to 4 cm. These substrates may typically be parallel to each other. It may be an advantage of embodiments of the present disclosure that they are particularly apt at allowing for a low precursor consumption for a particular coverage and/or for a high coverage at a particular precursor consumption in the case of such a plurality of substrates.

The deposited material may be formed from the sequential reaction of two or more precursors with the surface of the substrate. The majority of ALD reactions use two precursors. These precursors react with the surface of a material one at a time in a sequential, self-limiting, manner. A thin film is slowly deposited through repeated exposure to separate precursors.

The present disclosure can be applied to one or more of these precursors. In the typical case where two precursors are used, one of the precursors may be the precursor of a metal or of a metalloid and the second precursor may be a precursor of elementary oxygen or nitrogen. Since the metal or metalloid precursor may be, by far, the most expensive of both precursors, the present disclosure may particularly be useful when applied to the precursor of a metal or a metalloid.

The method may comprise a step of performing a pulse of a precursor of said material. The precursors may not be present simultaneously in the reactor, but they may be inserted as a series of sequential, non-overlapping pulses. Typically, in each of these pulses the precursor molecules may react with the surface in a self-limiting way, so that the reaction terminates once all the reactive sites on the surface are consumed. A pulse (or pulse duration) is the duration of the continuous presence of a precursor in the reactor. Pulses are separated by purges, that remove the precursor from the reactor.

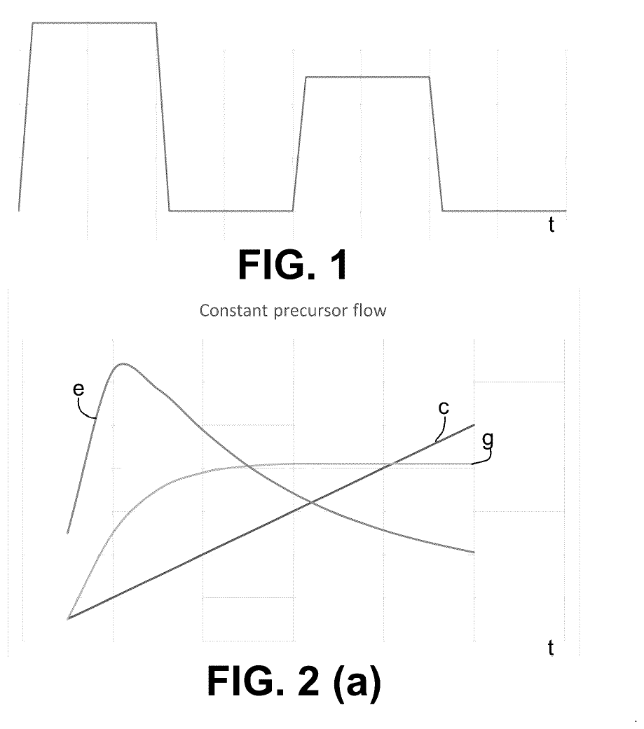

FIG. 1 shows a plot of a precursor parameter (flow rate or partial pressure) as a function of time for the prior art. The plot looks the same whether we look at the flow rate or at the partial pressure. The parameter is quickly increased at the beginning of the pulse until it reaches its desired value, then it is kept constant for almost the whole duration of the pulse, until it is decreased rapidly to zero. The average flow rate of the precursor over the first half of the pulse is the same as the average flow rate of the precursor over the second half of the pulse. Similarly, the average partial pressure of said precursor over the first half of the pulse is the same as the average partial pressure of said precursor over the second half of the pulse.

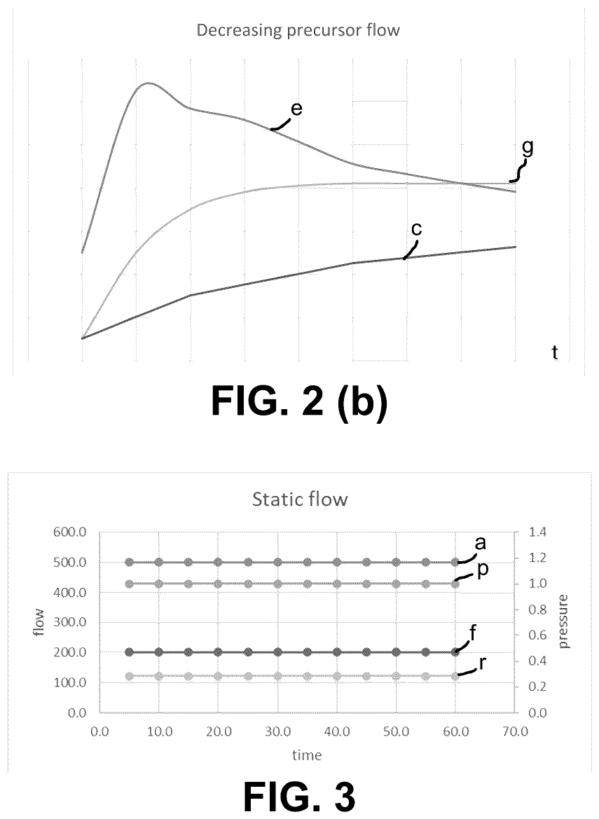

FIG. 2(a) are plots of a precursor consumption (c), growth per cycle (g), and efficiency (e) as a function of time (t) for a pulse in the prior art where the precursor flow is constant throughout the pulse.

FIG. 2(b) are plots of a precursor flow (f) as well as the associated precursor consumption (c), growth per cycle (g), and efficiency (e) as a function of time (t) for a pulse in an embodiment of the present disclosure. In FIG. 2(b), the flow is decreased by half twice during the precursor pulse. As can be observed by comparing FIG. 2(a) and FIG. 2(b), this improves the efficiency, defined as the ratio between the growth per cycle and the precursor consumption, of the pulse.

FIG. 3 is a plot of ALD process parameters as a function of time during a single pulse for the prior art. As can be observed, the precursor flow (f), the carrier flow (a), the pressure (p), and the partial pressure (r) of the precursor are kept constant during the entire pulse except at the very beginning and at the very end of the pulse, which are not depicted.

The present inventors have realised that by having at least one of the average flow rate and the average partial pressure of said precursor over a first half of the pulse comprising the start of the pulse being higher than over a second half of the pulse comprising the end of the pulse, a low precursor consumption for a particular coverage and/or for a high coverage at a particular precursor consumption may be achieved. In particular, a high flow rate and/or a high partial pressure may be beneficial to reach parts of the substrates that are not easily reached. However, once these parts have been covered, a lower flower rate and/or a lower partial pressure may be used until complete coverage of the substrate has been achieved.

The average flow rate of the precursor is a time averaged flow rate. The average partial pressure is a time averaged partial pressure.

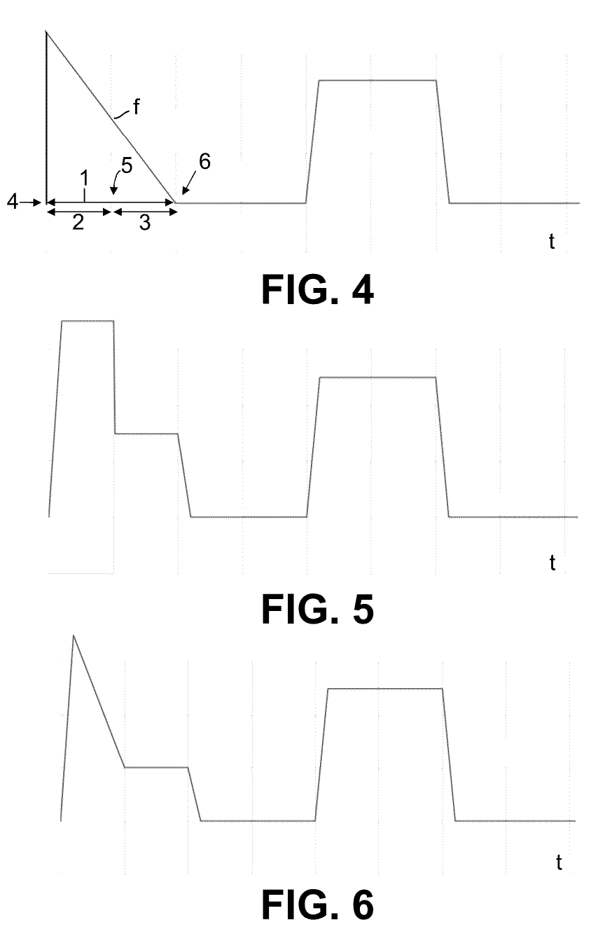

The first half (2) of the pulse (1) begins at the start (4) of the pulse duration (1) and ends at half (5) the pulse duration (1). The second half (3) of the pulse (1) begins at the half (5) of the pulse duration (1) and ends at the end (6) of the pulse (1). This is depicted in FIG. 4 for an embodiment of the present disclosure.

In embodiments, the average flow rate of said precursor may be higher over a first half of the pulse than over the second half of the pulse. This may be advantageous because this may allow to significantly decrease the precursor consumption while still ensuring a good substrate coverage.

In embodiments, the average flow rate of said precursor may be at least 10% higher, such as at least 20% higher, at least 30% higher, at least 40% higher, or at least 50% higher, or at least 100% higher over the first half of the pulse than over the second half of the pulse or at least 150% higher over the first half of the pulse than over the second half of the pulse.

It is to be noted that an average flow rate of zero cannot, by definition, happen during the pulse.

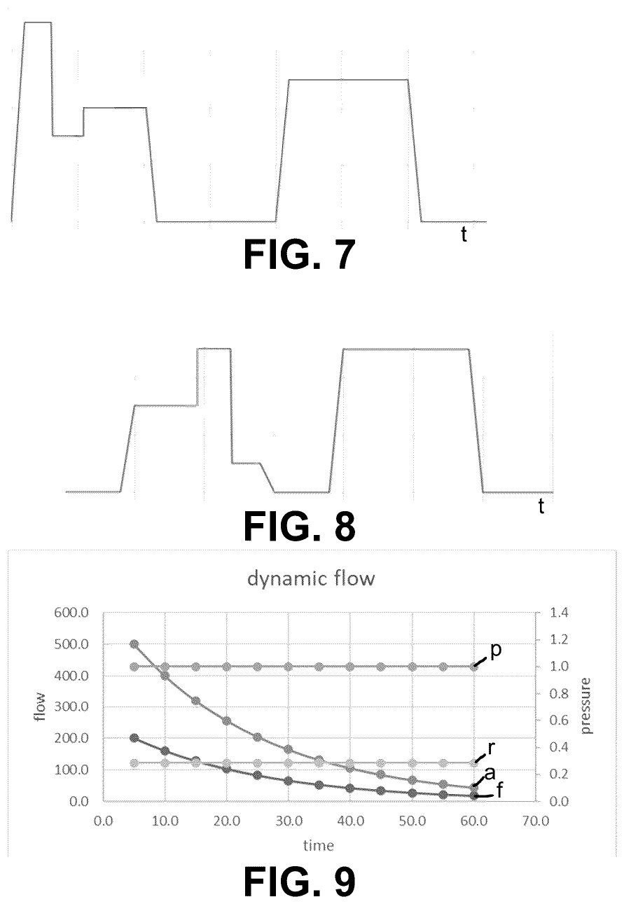

There may be no preferred upper limit to the percentage by which the average flow rate is higher over the first half of the pulse than over the second half of the pulse because this percentage tends to increase when the surface area of the substrate increases, and because this surface area can be arbitrarily increased by adding features on the substrate. For instance, the presence of features on the substrate (e.g., trenches) can increase the surface area by a very large factor, e.g., more than 300 times. However, some examples of upper limits to the percentage by which the average flow rate is higher over the first half of the pulse than over the second half of the pulse are 500%, 400%, 300%, and 250% but much higher limits than 500% are still within the present disclosure. FIG. 4 shows an average flow rate which is 200% higher over the first half of the pulse than over the second half of the pulse. FIG. 5 shows an average flow rate which is 126% higher over the first half of the pulse than over the second half of the pulse. FIG. 6 shows an average flow rate which is 119% higher over the first half of the pulse than over the second half of the pulse. FIG. 7 shows an average flow rate which is 21% higher over the first half of the pulse than over the second half of the pulse. FIG. 8 shows an average flow rate which is 2% higher over the first half of the pulse than over the second half of the pulse.

In embodiments, at least one of the average flow rate and the average partial pressure of said precursor may be higher over a first quarter of the pulse than over the second quarter of the pulse, higher over the second quarter of the pulse than over the third quarter of the pulse, and higher over the third quarter of the pulse than over the fourth quarter of the pulse. This is, for instance, the case in FIGS. 4 and 9.

In embodiments, the average flow rate of said precursor may decrease continuously over at least 40%, preferably over at least 50%, more preferably over at least 60%, yet more preferably over at least 70%, even more preferably, over at least 80%, and most preferably over at least 90% of the pulse. In FIGS. 4 and 9, it decreases continuously over 100% of the pulse. In FIG. 6, it decreases continuously over 47% of the pulse.

In embodiments, the flow rate of said precursor may be constant during at least 60% of the first half of the pulse. This is the case in FIG. 5 and in FIG. 8. Preferably, the flow rate of said precursor may be constant and at its highest level during at least 60% of the first half of the pulse. This may be advantageous as it may allow for achieving a better and faster coverage of surfaces that are difficulty to reach, before to decrease the rate of the precursor until saturation of the surfaces is reached.

In embodiments, the average flow rate of said precursor over a first half of the pulse may be from 25 sccm to 1500 sccm.

When the average flow rate of said precursor is higher over the first half of the pulse than over the second half of the pulse, it may be advantageous to keep the average partial pressure of said precursor over the first half of the pulse within 5%, or even within 1% of the average partial pressure of said precursor over the second half of the pulse. Keeping the partial pressure the same during the entire pulse may be advantageous to maintain good process performances. Maintaining the partial pressure of the precursor while the precursor flow decreases implies reducing the flow of the other gases (carrier gas and any auxiliary gas) in line with the decrease of the flow of the precursor gas. This is depicted in FIG. 9.

When the average flow rate of said precursor is not higher over a first half of the pulse than over the second half of the pulse, the average partial pressure of said precursor may higher over the first half of the pulse than over the second half of the pulse.

When the average flow rate of said precursor is higher over a first half of the pulse than over the second half of the pulse, the average partial pressure of said precursor may also be higher over the first half of the pulse than over the second half of the pulse. FIGS. 4 to 8 can also show the evolution of the partial pressure of the precursor over the time of the pulse, instead of showing the evolution of the flow of the partial pressure over the time of the pulse.

Hence, the average partial pressure of said precursor may be higher over the first half of the pulse than over the second half of the pulse.

In embodiments, the partial pressure of said precursor may be constant during at least 90% the first half of the pulse and the average partial pressure may decrease during the second half of the pulse.

Reducing the partial pressure of the precursor over the second half of the pulse may be advantageous to improve the uniformity of the surface coverage. In embodiments, this may be achieved by decreasing the precursor flow while either not decreasing the flow of the other gases introduced in the reactor or not decreasing them sufficiently to keep the partial pressure of the precursor constant. In other embodiments, this may be achieved by maintaining the precursor flow constant while increasing the flow of the other gases introduced in the reactor. In yet other embodiments, it may be achieved by increasing the precursor flow while increasing the flow of the other gases introduced in the reactor more than what would be sufficient to maintain the partial pressure constant.

In embodiments, the precursor pulse may last from 1 s to 180 s.

Any features of the first aspect may be as correspondingly described in the other aspects of the present disclosure.

The precursor may be silicon based and may comprise, for example, halides such as Dichlorosilane (DC S), Hexachlorodisilane (HCDS), Bis(diethylamino)silane (BDEASi) or Octachlorotrisilane (OCTS).

The precursor may comprise a metal (e.g. Titanium, Vanadium, Molybdenum, Niobium, Tantalum, Aluminum, Hafnium, Zirconium). The metal precursor may, for example, comprise halides such as Titanium tetrachloride (TiCl₄), Vanadium tetrachloride (VCl₄), Molybdenum pentachloride (MoCl₅), Molybdenum dioxidichloride (MoO₂Cl₂), Niobium pentachloride (NbCl₅), Tantalum pentachloride (TaCl₅), Aluminum trichloride (AlCl₃), Hafnium tetrachloride (HfCl₄), Zirconium tetrachloride (ZrCl₄).

The precursor may also comprise a metal and substantially without halides such, as for example, Trimethyl aluminum (TMA), Tetrakis(ethylmethylamino) hafnium, Tetrakis(ethylmethylamino) zirconium, Cyclopentadienyl hafnium, Cyclopentadienyl zirconium, Tris(dimethylamino)cyclopentadienyl Hafnium, Tris(dimethylamino)cyclopentadienyl Zirconium, Bis(methylcyclopentadienyl)methoxymethyl Hafnium, Bis(methylcyclopentadienyl)methoxymethyl Zirconium, and Tetrakis(dimethylamino) titanium.

In the second aspect, the present disclosure relates to a system comprising an atomic layer deposition reactor and means adapted to execute the method of the first aspect.

In embodiments, the atomic layer deposition reactor may be a vertical furnace batch atomic layer deposition reactor.

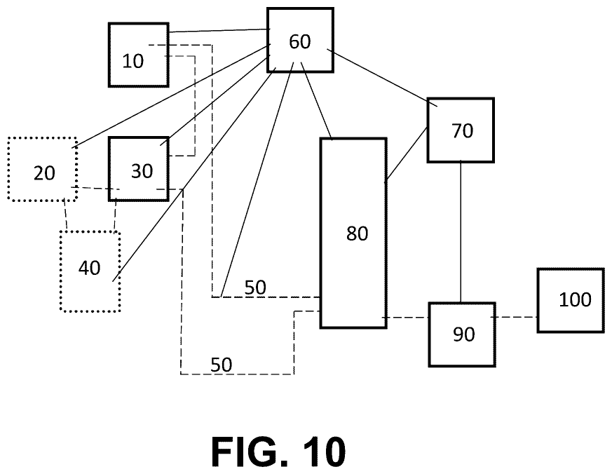

We now refer to FIG. 10. In FIG. 10, dashed lines indicate fluidic connections and plain lines indicate electrical coupling. Dotted rectangles indicate elements that are typically optional. Plain rectangles indicate elements that are typically present. The system typically comprises:
a reactor (80),
a heater disposed within the reactor (80) suitable for heating a process chamber of the reactor (80) to a process temperature,
at least one of a precursor flow control valve (30) for mechanically adapting the flow of the precursor and of a carrier gas (10) flow control valve (10) for mechanically adapting the flow of the carrier gas,
optionally, one or more further gas flow control valves for mechanically adapting the flow of one or more further gases,
fluidic connections (50) to deliver gas from the flow control valves (30, 10) to the process chamber of the reactor (80),
a gas exhaust module (100) for removing a portion of the gases present in the process chamber of the reactor (80),
a pressure control valve (90) downstream of the process chamber of the reactor (80), for mechanically adapting the flow of gas removed from the process chamber by the gas exhaust module (100),
optionally, a pressure control unit (70) configured for adapting, e.g., maintaining, the process pressure in the process chamber by sending a signal to the pressure control valve indicating the desired pressure, thereby controlling the pressure control valve.
optionally, a precursor storage module (20) for comprising a precursor and for delivering the precursor via the precursor flow control valve (30) and via a fluidic connection (50) to the process chamber of the reactor (80),
optionally, a carrier gas storage module for comprising a carrier gas and for delivering the carrier gas via the carrier flow control valve (10) and via a fluidic connection (50) to the process chamber of the reactor (80),
optionally, further gas storage modules, each for comprising a further gas and for delivering the further gas via one of the one or more further flow control valves and via one of the one or more fluidic connections (50) to the process chamber of the reactor (80),
a control unit (60) configured for executing the steps of the method of the first aspect (e.g., via instructions comprised in a memory such as a (e.g., non-transitory) computer readable medium) to cause the system to form a material (of which the precursor is a precursor) on one or more substrates in accordance with a method according to any embodiments of the first aspect.

The flow control valves (10, 30) each may comprise an inlet for fluidly connecting with a storage module (20) or for fluidly connecting with a mass flow sensor (40).

Preferably, a precursor flow control valve (30) may be present.

In some embodiments, one or more of the flow control valves (30, 10) may each form part of a mass flow controller. Each mass flow controller may then comprise the flow control valve (30 or 10) as well as a mass flow sensor (40) fluidly connected with the flow control valve and with an inlet of the mass flow controller for fluidly connecting with a precursor storage module (20).

Each mass flow controller may operate by receiving an input signal from the control unit (60) indicating the desired flow, comparing the desired flow to the value from the mass flow sensor (40) and adjusting the precursor flow control valve (30) accordingly to achieve the desired flow.

Fluidic connections may be present between the reactor (80) and each of the pressure control valve (90) and the flow control valves (30, 10).

Fluidic connections may also be present between storage modules (20) and the corresponding flow control valves (10, 30).

Fluidic connections may also be present between the pressure control valve (90) and the gas exhaust module.

In embodiments, the control unit (60) may be operably connected (typically electrically connected but other connections, e.g., hydraulic connections, are also possible) to one or more of the following: the heater for setting the process temperature, the one or more flow control valves (30) or the one or more mass flow controllers for setting the corresponding flows, the pressure control unit (70) for setting the pressure in the chamber,

Any features of the second aspect may be as correspondingly described in the other aspects of the present disclosure.

In a third aspect, the present disclosure relates to a computer program comprising instructions to cause the system of the second aspect to execute the method of the second aspect.

Any features of the third aspect may be as correspondingly described in the other aspects of the present disclosure.

In a fourth aspect, the present disclosure relates to a computer-readable medium having stored thereon the computer program of the third aspect.

Any features of the fourth aspect may be as correspondingly described in the other aspects of the present disclosure.

It is to be understood that although preferred embodiments, specific constructions and configurations, as well as materials, have been discussed herein for devices according to the present disclosure, various changes or modifications in form and detail may be made without departing from the scope of this disclosure. For example, any formulas given above are merely representative of procedures that may be used. Functionality may be added or deleted from the block diagrams and operations may be interchanged among functional blocks. Steps may be added or deleted to methods described within the scope of the present disclosure.

1. A method for depositing a material on a substrate in a reaction chamber by an atomic layer deposition method, the method comprising a step of providing a pulse of a precursor for said material, wherein at least one of an average flow rate and an average partial pressure of said precursor over a first half of the pulse is higher than over a second half of the pulse.

2. The method according to claim 1, wherein the average flow rate of said precursor is higher over a first half of the pulse than over the second half of the pulse.

3. The method according to claim 2, wherein the average flow rate of said precursor is at least 10% higher over the first half of the pulse than over the second half of the pulse.

4. The method according to claim 3, wherein the average flow rate of said precursor is at least 50% higher over the first half of the pulse than over the second half of the pulse.

5. The method according to claim 4, wherein the average flow rate of said precursor is at least 150% higher over the first half of the pulse than over the second half of the pulse.

6. The method according to claim 1, wherein the average flow rate of said precursor decreases continuously over at least 40% of the pulse.

7. The method according to claim 6, wherein the average flow rate of said precursor decreases continuously over at least 50% of the pulse.

8. The method according to claim 7, wherein the average flow rate of said precursor decreases continuously over at least 70% of the pulse.

9. The method according to claim 8, wherein the average flow rate of said precursor decreases continuously over at least 90% of the pulse.

10. The method according to claim 1, wherein a flow rate of said precursor is constant during at least 60% of the first half of the pulse.

11. The method according to claim 1, wherein the first half of the pulse comprises the start of the pulse and the second half of the pulse comprises the end of the pulse.

12. The method according to claim 2, wherein the average partial pressure of said precursor over the first half of the pulse is within 5% of the average partial pressure of said precursor over the second half of the pulse.

13. The method according to claim 12, wherein the average partial pressure of said precursor over the first half of the pulse is within 1% of the average partial pressure of said precursor over the second half of the pulse.

14. The method according to claim 1, wherein the average partial pressure of said precursor is higher over the first half of the pulse than over the second half of the pulse.

15. The method according to claim 14, wherein a partial pressure of said precursor is constant during at least 90% the first half of the pulse and the average partial pressure decreases during the second half of the pulse.

16. The method according to claim 1, wherein the substrate is one of a plurality of substrates mutually separated by a distance of from 3 mm to 10 cm.

17. The method according to claim 1, wherein the pulse lasts from 1 s to 180 s.

18. A system for depositing a material on a substrate comprising:
a process chamber,
a heater for heating the process chamber,
a precursor flow control valve controlling a flow of a precursor to the process chamber,
a pressure control valve downstream of the process chamber for controlling a flow of gas from the process chamber to a gas exhaust module for removing gas from the process chamber, and a control unit operably connected to the precursor flow control valve and/or the pressure control valve and provided with a memory, wherein the control unit is configured for executing an atomic layer deposition method stored in the memory by controlling the precursor flow valve to provide a pulse of the precursor whereby the precursor flow control valve and or the pressure control valve is controlled to have at least one of the average flow rate and the average partial pressure of said precursor over a first half of the pulse is higher than over a second half of the pulse.

19. The system according to claim 18, further comprising an atomic layer deposition reactor including the process chamber, wherein the atomic layer deposition reactor is a vertical furnace batch atomic layer deposition reactor.
